(19) United States
(12) Patent Application Publication
(10) Pub. No.: US 2016/0041229 A1
(43) Pub. Date: Feb. 11, 2016

(54) APPARATUS AND METHOD FOR ESTIMATING A BATTERY STATE OF CHARGE

(71) Applicant: HYUNDAI MOBIS CO., LTD., Seoul (KR)

(72) Inventors: Ho-Young PARK, Anyang-si (KR); Chang-Youl CHOI, Yongin-si (KR)

(73) Assignee: HYUNDAI MOBIS CO., LTD., Seoul (KR)

(21) Appl. No.: 14/813,495

(22) Filed: Jul. 30, 2015

(30) Foreign Application Priority Data
Aug. 5, 2014 (KR) 10-2014-0100374

(51) Int. Cl. G01R 31/36

(52) U.S. Cl. CPC G01R 31/3624; G01R 31/3662; G01R 31/3651

(57) ABSTRACT

An apparatus for estimating battery state of charge may include a sensor configured to sense a voltage value and a current value of a battery, an internal resistance calculator configured to calculate an internal resistance using the voltage value and the current value, a noise remover configured to determine an output accumulation method or an open circuit using method using an open circuit voltage to remove a noise due to the internal resistance, an output accumulator configured to accumulate and calculate a residual capacity of the battery depending on the output accumulation method, a compensated state of charge calculator configured to calculate a compensated state of charge of the battery using a preset lookup table depending on the open circuit using method, and a battery state of charge estimator configured to calculate an estimated state of charge of the battery using the residual capacity or the compensated state of charge.

### CROSS-REFERENCE(S) TO RELATED APPLICATIONS

This application claims the benefit under 35 USC 119(a) of Korean Patent Application No(s). 10-2014-0100374 filed on Aug. 05, 2014 in the Korean Intellectual Property Office, the entire disclosure of which is incorporated herein by reference in its entirety.

### BACKGROUND

1. Field

Embodiments of the present application relate to an apparatus and a method for more accurately estimating a battery state of charge by using an internal resistance threshold value as a current noise filter while applying a mixing method of accumulating energy (Wh) at the time of actually charging and discharging a battery from load side energy and loss energy (Wh).

2. Description of Related Art

FIG. 1 is a conceptual diagram of an estimation of a general battery state of charge (SOC) according to the related art. Referring to FIG. 1, an apparatus for estimating a battery state of charge is configured to include a battery pack 110, a voltage sensor 121, a current sensor 122, a memory unit 130, a controller 140, and the like. Referring to FIG. 1, a voltage value and a current value which are sensed by the voltage sensor 121 and the current sensor 122 are stored in the memory unit 130 and the controller 140 uses the voltage value and the current value, respectively, to calculate load side energy (Wh) and calculates battery loss (Wh) to calculate battery residual energy (Wh). The state of charge is estimated based on the residual energy.

In this case, the voltage value and the current value which are sensed by the voltage sensor and the current sensor are the voltage/current values of the load side as voltage and current values of an output terminal of a battery pack. In particular, the voltage value is a value distorted due to an internal resistance of the battery, and therefore it is difficult to estimate the battery state of charge (SOC) based on the voltage value.

For this reason, when the current value is 0 or approximates 0, an internal resistance (R) value is abnormally increased, and as a result, appears as an error of a load side output (W) value. This leads to an accumulation error of energy (Wh) and therefore the SOC calculation is continuously wrong from then. As a result, the wrong value is derived.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, an apparatus for estimating a battery state of charge may include a sensor configured to sense a voltage value and a current value of a battery, an internal resistance calculator configured to calculate an internal resistance using the voltage value and the current value, a noise remover configured to determine an output accumulation method, or an open circuit using method, using an open circuit voltage to remove a noise due to the internal resistance, an output accumulator configured to accumulate and calculate a residual capacity of the battery depending on the output accumulation method, a compensated state of charge calculator configured to calculate a compensated state of charge of the battery using a preset lookup table depending on the open circuit using method, and a battery state of charge estimator configured to calculate an estimated state of charge of the battery using the residual capacity or the compensated state of charge.

The apparatus may be configured such that the internal resistance is calculated using the current value, a unique voltage value of the battery, and the voltage value.

The apparatus may be configured such that the output accumulator includes a load side energy calculator configured to calculate an output capacity (W) of the battery using the internal resistance, the battery, and the load and to convert the output capacity into energy (Wh), and a residual capacity calculator configured to calculate residual capacity (Ah) depending on a preset conversion relational expression with the energy (Wh).

The apparatus may be configured such that the estimated state of charge is calculated by dividing the residual capacity by a preset design capacity.

The apparatus may be configured such that the lookup table has a previously matched state of charge (SOC) corresponding to an open circuit voltage (OCV: open).

The apparatus of claim 5, wherein the compensated state of charge is a state of charge in which a corresponding open circuit voltage is added to a preset specific value.

The apparatus may be configured such that the noise remover selects the open circuit using method when the internal resistance is larger than a preset threshold resistance value and the current value is 0, and selects the output accumulation method when the internal resistance is smaller than the preset threshold resistance value and the current value is not 0.

The apparatus may further include a battery initial state of charge estimator configured to calculate a battery initial state of charge using the preset lookup table, when the current value and the voltage value are delayed by a predetermined time or more.

The apparatus may be configured such that the internal resistance is calculated by Equation R=±{(V−OCV)/I}, wherein I represents the current value, OCV represents the unique voltage value of the battery, ±represents a current sign, and V represents the voltage value.

In one general aspect, a method for estimating a battery state of charge may include a step of sensing a voltage value and a current value of a battery, a step of calculating an internal resistance using the voltage value and the current value, a noise removing step of determining an output accumulation method or an open circuit using method using an open circuit voltage to remove a noise due to the internal resistance, an output accumulating step of accumulating and calculating a residual capacity of the battery depending on the output accumulation method, a compensated state of charge calculating step of calculating a compensated state of charge of the battery using a preset lookup table depending on the open circuit using method, and a battery state of charge estimating step of calculating an estimated state of charge of the battery using the residual capacity or the compensated state of charge.

The method may include a process wherein the internal resistance is calculated using the current value, a unique voltage value of the battery, and the voltage value.

The method may include a process wherein the accumulating of the output includes a step of calculating an output capacity (W) of the battery using the internal resistance, the battery, and the load and converting the output capacity into energy (Wh), and a step of calculating residual capacity (Ah) depending on a preset conversion relational expression with the energy (Wh).

The method may include a process wherein the estimated state of charge is calculated by dividing the residual capacity by a preset design capacity.

The method may include a process wherein the lookup table has a previously matched state of charge (SOC) corresponding to an open circuit voltage (OCV: open).

The method may include a process wherein the compensated state of charge is a state of charge in which a corresponding open circuit voltage is added to a preset specific value.

The method may include a process wherein the noise removing step includes comparing the internal resistance with preset values to select the open circuit using method when the internal resistance is larger than a preset threshold resistance value and the current value is 0, and selecting the output accumulation method when the internal resistance is smaller than the preset threshold resistance value and the current value is not 0.

The method may further include a battery initial state of charge estimating step of calculating a battery initial state of charge using the preset lookup table, when the current value and the voltage value are delayed by a predetermined time or more.

The method may include a process wherein the internal resistance is calculated by Equation R=±{(V−OCV)/I}, wherein I represents the current value, OCV represents the unique voltage value of the battery, ±represents a current sign, and V represents the voltage value.

Other features and aspects will be apparent from the following detailed description, the drawings, and the claims

### BRIEF DESCRIPTION OF THE DRAWINGS

FIG. 1 is a conceptual diagram of an estimation of a general battery state of charge according to the related art.

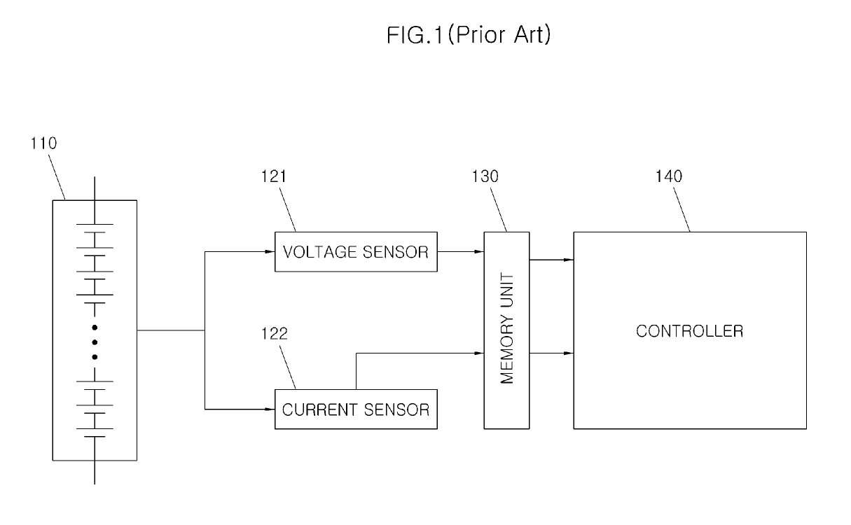

FIG. 2 is a block diagram illustrating an example of a configuration of an apparatus for estimating a battery state of charge.

FIG. 3 is an equivalent model diagram.

FIG. 4 is a flow chart illustrating an example of a process of estimating a battery state of charge (SOC) using an open circuit voltage (OCV) table and an internal resistance (R).

### DETAILED DESCRIPTION

The following detailed description is provided to assist the reader in gaining a comprehensive understanding of the methods, apparatuses, and/or systems described herein. However, various changes, modifications, and equivalents of the systems, apparatuses and/or methods described herein will be apparent to one of ordinary skill in the art. The progression of processing steps and/or operations described is an example; however, the sequence of and/or operations is not limited to that set forth herein and may be changed as is known in the art, with the exception of steps and/or operations necessarily occurring in a certain order. Also, descriptions of functions and constructions that are well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will convey the full scope of the disclosure to one of ordinary skill in the art

Throughout the accompanying drawings, the same reference numerals will be used to describe the same components.

Terms used in the specification, ‘first’, ‘second’, etc., may be used to describe various components, but the components are not to be interpreted to be limited to the terms. The terms are used to distinguish one component from another component.

Therefore, the first component may be referred to as the second component, and the second component may be referred to as the first component. The term ‘and/or’ includes a combination of a plurality of items or any one of a plurality of terms.

Unless indicated otherwise, it is to be understood that all the terms used in the specification including technical and scientific terms has the same meaning as those that are understood by those who skilled in the art.

It must be understood that the terms defined by the dictionary are identical with the meanings within the context of the related art, and they should not be ideally or excessively formally defined unless the context clearly dictates otherwise.

Hereinafter, an apparatus and a method for estimating a battery state of charge according to embodiments of the present application will be described with reference to the accompanying drawings.

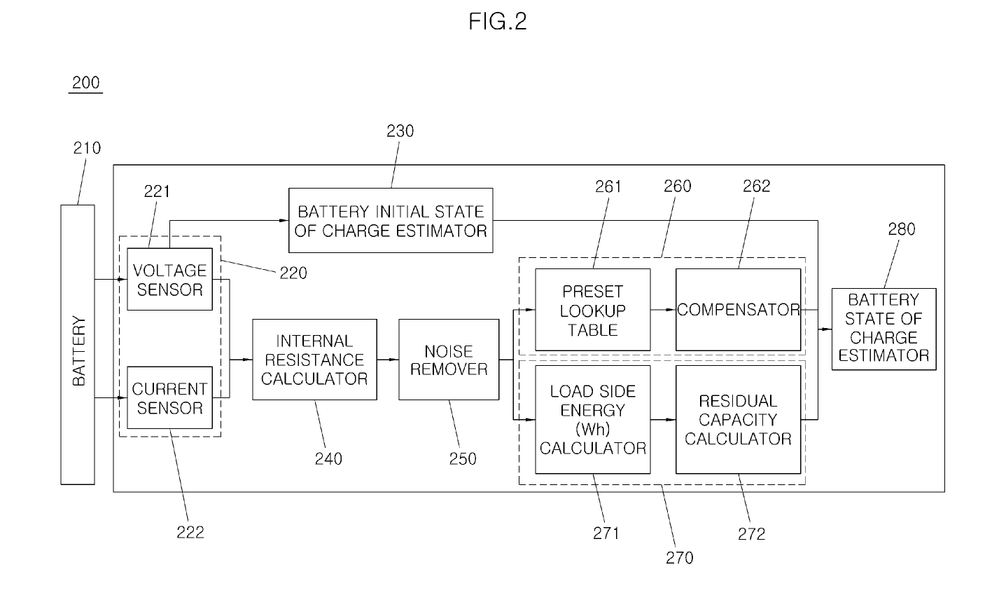

FIG. 2 is a block diagram illustrating an example of a configuration of an apparatus 200 for estimating a battery state of charge. Referring to FIG. 2, the apparatus 200 for estimating a battery state of charge includes a battery 210, a sensor 220 configured to sense a voltage value and a current value of the battery 210, an internal resistance calculator 240 configured to calculate an internal resistance using the voltage value and the current value, a noise remover 250 configured to determine an output accumulation method or an open circuit using method using an open circuit voltage to remove a noise due to the internal resistance, an output accumulator 270 configured to accumulate and calculate a residual capacity of the battery 210 depending on the output accumulation method, a compensated state of charge calculator 260 configured to calculate a compensated state of charge of the battery 210 using a preset lookup table depending on the open circuit using method, a battery state of charge estimator 280 configured to calculate an estimated state of charge of the battery 210 using the residual capacity or the compensated state of charge, a battery initial state of charge estimator 230 configured to estimate a battery initial state of charge, and the like.

The battery 210 may have a pack form or may be a single battery. Further, the battery 210 is configured of battery cells which are connected in series and/or in parallel, in which the battery cell may be a high voltage battery for an electric vehicle such as a nickel metal battery and a lithium ion battery. Generally, the high voltage battery is a battery used as a power source which moves the electric vehicle, which means a high voltage battery of 100 V or more. However, embodiments of the present application are not limited thereto, and therefore a low voltage battery may be used. Herein, an example of the electric vehicle may include an electric vehicle (EV), a hybrid electric vehicle (HEV), a plug-in hybrid electric vehicle (PHEV), a fuel cell vehicle, and the like.

The sensor 220 is configured to include a voltage sensor 221 sensing the voltage value of the battery 210 and a current sensor 222 sensing the current value of the battery 210.

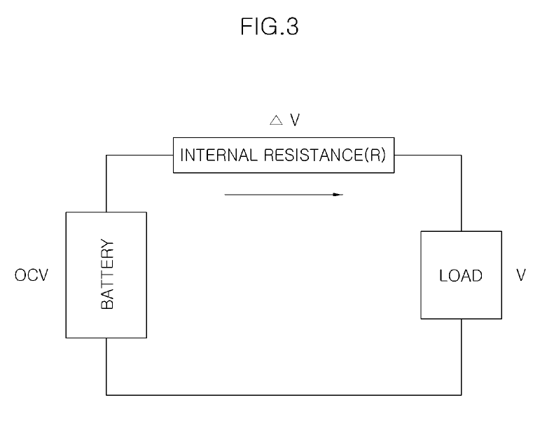

The internal resistance calculator 240 calculates an internal resistance (R) using the current value, a unique voltage value of the battery, and the voltage value. A diagram illustrating a calculation concept of the internal resistance (R) is illustrated in FIG. 3. This will be described below.

Referring to FIG. 2, the output accumulator 270 implements an output accumulation method. The output accumulator 270 is configured to include a load side energy calculator 271 which calculates an output capacity (W) of the battery 210 using the internal resistance (R), the battery 210, and a load and converts the output capacity into energy (Wh), a residual capacity calculator 272 which calculates a residual capacity (Ah) depending on a preset conversion relational expression with the energy (Wh), and the like. In particular, the output accumulator 270 accumulates the energy (Wh) at the time of actually charging and discharging the battery 210 from load side energy and loss energy (Wh) to calculate the residual capacity.

The compensated state of charge calculator 260 is configured to include a preset lookup table 261, a compensator 262 which adds a compensation factor to the state of charge calculated by using the lookup table 261 to calculate the compensated state of charge, and the like.

In other words, an input value is used as the current value and the voltage value and is converted in order of output (W) energy (Wh) capacity (Ah), thereby calculating a final SOC. The state of charge (SOC) may be estimated by a relational expression of load energy and loss energy of the battery 210. However, the SOC estimation value is highly likely to be different depending on a resistance portion of the loss energy (=12 R).

Therefore, the SOC is estimated by an output accumulation method and an open circuit using method which are two methods depending on a comparison of the calculated internal resistance (R) with a preset threshold value. In the case of the output accumulation method, when the current value is 0 or approximates 0, the internal resistance value appears as an infinite or a large value. For this reason, if it is determined that the internal resistance value is equal to or less than the preset threshold value, the load side energy and the loss energy which are normally used are converted into Ah and then the residual capacity is obtained.

On the other hand, in the case of the open circuit using method, if it is determined that the internal resistance value is equal to or more than the preset threshold value, the load side is considered as an unloading state and thus the SOC is obtained by the preset lookup table.

Here, the lookup table is a SOC vs OCV table in which the state of charge (SOC) is previously matched corresponding to an open circuit voltage (OCV: open).

Further, the apparatus 100 for estimating a battery state of charge is configured to include the battery initial state of charge estimator 230 which calculates the battery initial state of charge using the preset lookup table when the current value and the voltage value are delayed by a predetermined time or more.

FIG. 3 is an equivalent model diagram. Referring to FIG. 3, the OCV is a unique voltage (voltage when a current is not applied) of the battery and the voltage value (V) is a voltage applied to a load when a current is practically applied and the internal resistance (R) represents a loss value which exits to the outside through an electric wire, and the like. Therefore, in the case of the charging standard, the internal resistance may be defined by the following Equation.

### [Equation 1]

Internal resistance (R)=(V−OCV)/1

On the other hand, in the case of the discharging standard, the internal resistance may be defined by the following Equation.

### [Equation 2]

Internal resistance (R)=(OCV−V)/1

Therefore, the internal resistance is calculated by applying one of the above Equations depending on a current sign.

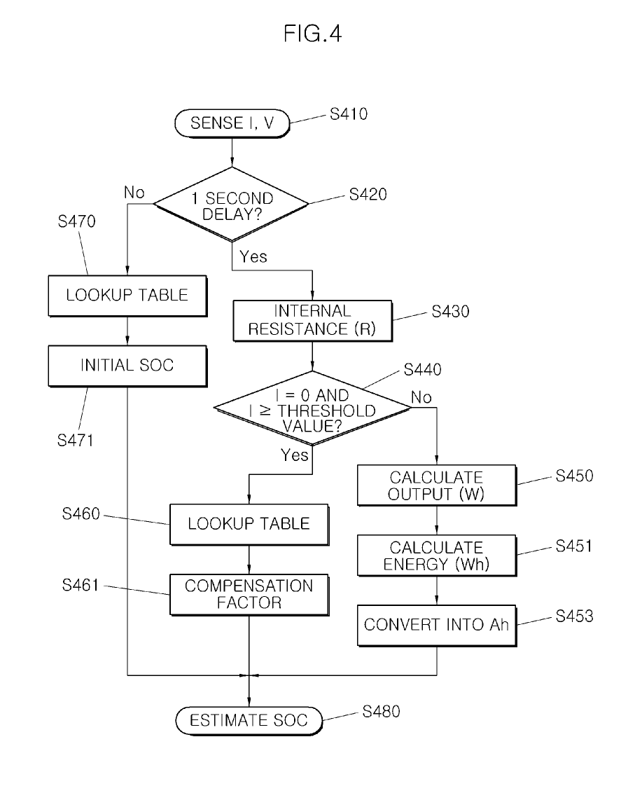

FIG. 4 is a flow chart illustrating an example of a process of estimating a battery state of charge (SOC) using the open circuit voltage (OCV) table and the internal resistance (R). Referring to FIG. 4, the voltage value and/or current value of the battery 210 (FIG. 2) are sensed by the sensor 220 (FIG. 2) (step S410).

After the sensing, it is determined whether the output of the voltage value and/or the current value is delayed by the predetermined time or more (for example, about 1 second) (step S420).

In step S420, as the determination result, if it is determined that the output of the voltage value and/or the current value is delayed by the predetermined time or more, steps S430 to S461 or steps S430 to S453 are performed. In other words, if it is determined that the output of the voltage value and/or the current value is delayed by the predetermined time or more, the internal resistance (R) is calculated (step S430).

When the internal resistance (R) is calculated, the internal resistance is compared with the preset values (step S440). In other words, when the internal resistance (R) is larger than the preset threshold resistance value (any preset value) and the current value (I) is 0, the open circuit using method is selected (steps S460 and S461).

In other words, since the battery 210 (FIG. 2) is in the unloading state, no energy loss due to the internal resistance is present and thus the state of charge (SOC) is estimated by the open circuit voltage (OCV) of the battery itself.

For understanding, for example, if it is assumed that threshold resistance value =10 Ω, input current =0.1 A, input voltage =273 V, battery OCV =270 V, the internal resistance is as follows.

R=(273−270)/0.1=30

Accordingly, since the internal resistance (R) is larger than the threshold resistance value (1 Ω), the SOC is calculated by the lookup table (that is, OCV-SOC relation table).

Here, the OCV value becomes 270 V+α (α is a previously obtained value) and thus the SOC therefor is estimated. In other words, since the battery has a property of returning to its own potential, a relaxation effect needs to be considered, and therefore compensation is performed using a compensation factor to generate a compensated state of charge (SOC) (steps S460 and 461).

On the other hand, in step S440, when the internal resistance (R) is smaller than the preset threshold resistance value and the current value (I) is not 0, the output accumulation method is performed (steps S450, S451, and S453).

That is, the output value is calculated by the relational expression of the battery, the load, and the internal resistance, which is then calculated as Wh. Next, the Wh is finally converted into Ah and thus the SOC is calculated. In other words, this is as follows.

a) Battery output (W)=load output (W)+loss output (W)

b) Since a sampling time of the battery output (W) obtained in a) is per 1 second, Wh is calculated by dividing the battery output(W) with 3600.

c) The Wh is converted into Ah based on the previously obtained Wh-Ah.

d) Residual capacity (Ah)/design capacity (Ah)=estimated SOC

Here, the design capacity is a preset value.

Meanwhile, in step S420, as the determination result, if it is determined that the output of the voltage value and/or the current value is not delayed by 1 second or more, steps S470 to S471 are performed. In other words, the battery initial state of charge is calculated based on the preset lookup table (steps S470 and S471).

Next, the estimated SOC is finally calculated (step S480).

According to embodiments of the present application, a product of the sensing voltage which is an appearance value and the current is defined as the load side output (W) and a value obtained by integrating the product is defined as the load side energy (Wh). Further, the loss energy (Wh) is calculated by estimating Joule's heat loss 12 R due to the internal resistance (R) and thus the battery state of charge (SOC) is estimated based on an energy amount which is actually stored in the battery and then is emitted.

In particular, according to embodiments of the present application, the battery state of charge is estimated by using the resistance value varying depending on temperature which is projected to the appearance voltage value, without using a temperature sensor.

In other words, a method for applying a compensation factor to a lookup table depending on the internal resistance of the battery and a method for estimating a battery state of charge based on the load side energy and the loss energy depending on the threshold value using the internal resistance value are used.

As the input value, only the current value and the voltage value other than the temperature are used and the internal resistance is used as a kind of current noise removing filter to distinguish the state of charge estimation method depending on the value, thereby more accurately obtaining the estimation value.

According to embodiments of the present application, it is possible to more accurately estimate the state of charge by using the internal resistance threshold value as the current noise filter while applying the mixing method of accumulating energy (Wh) at the time of actually charging and discharging the battery from the load side energy and the loss energy (Wh).

Further, according to embodiments of the present application, it is possible to estimate the battery state of charge without using the temperature sensor by using the resistance value varying in response to the temperature which is projected to the appearance voltage value.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. An apparatus for estimating a battery state of charge, the apparatus comprising:
a sensor configured to sense a voltage value and a current value of a battery;
an internal resistance calculator configured to calculate an internal resistance using the voltage value and the current value;
a noise remover configured to determine an output accumulation method, or an open circuit using method, using an open circuit voltage to remove a noise due to the internal resistance;
an output accumulator configured to accumulate and calculate a residual capacity of the battery depending on the output accumulation method;
a compensated state of charge calculator configured to calculate a compensated state of charge of the battery using a preset lookup table depending on the open circuit using method; and
a battery state of charge estimator configured to calculate an estimated state of charge of the battery using the residual capacity or the compensated state of charge.

2. The apparatus of claim 1, wherein the internal resistance is calculated using the current value, a unique voltage value of the battery, and the voltage value.

3. The apparatus of claim 1, wherein the output accumulator includes:
a load side energy calculator configured to calculate an output capacity (W) of the battery using the internal resistance, the battery, and the load and to convert the output capacity into energy (Wh); and
a residual capacity calculator configured to calculate residual capacity (Ah) depending on a preset conversion relational expression with the energy (Wh).

4. The apparatus of claim 3, wherein the estimated state of charge is calculated by dividing the residual capacity by a preset design capacity.

5. The apparatus of claim 1, wherein the lookup table has a previously matched state of charge (SOC) corresponding to an open circuit voltage (OCV: open).

6. The apparatus of claim 5, wherein the compensated state of charge is a state of charge in which a corresponding open circuit voltage is added to a preset specific value.

7. The apparatus of claim 1, wherein the noise remover selects the open circuit using method when the internal resistance is larger than a preset threshold resistance value and the current value is 0, and selects the output accumulation method when the internal resistance is smaller than the preset threshold resistance value and the current value is not 0.

8. The apparatus of claim 1, further comprising:
a battery initial state of charge estimator configured to calculate a battery initial state of charge using the preset lookup table, when the current value and the voltage value are delayed by a predetermined time or more.

9. The apparatus of claim 2, wherein the internal resistance is calculated by Equation R=±{(V−OCV)/I},
wherein I represents the current value, OCV represents the unique voltage value of the battery, ±represents a current sign, and V represents the voltage value.

10. A method for estimating a battery state of charge, the method comprising:
a step of sensing a voltage value and a current value of a battery;
a step of calculating an internal resistance using the voltage value and the current value;
a noise removing step of determining an output accumulation method or an open circuit using method using an open circuit voltage to remove a noise due to the internal resistance;
an output accumulating step of accumulating and calculating a residual capacity of the battery depending on the output accumulation method;
a compensated state of charge calculating step of calculating a compensated state of charge of the battery using a preset lookup table depending on the open circuit using method; and
a battery state of charge estimating step of calculating an estimated state of charge of the battery using the residual capacity or the compensated state of charge.

11. The method of claim 10, wherein the internal resistance is calculated using the current value, a unique voltage value of the battery, and the voltage value.

12. The method of claim 10, wherein the accumulating of the output includes:
a step of calculating an output capacity (W) of the battery using the internal resistance, the battery, and the load and converting the output capacity into energy (Wh); and
a step of calculating residual capacity (Ah) depending on a preset conversion relational expression with the energy (Wh).

13. The method of claim 12, wherein the estimated state of charge is calculated by dividing the residual capacity by a preset design capacity.

14. The method of claim 12, wherein the lookup table has a previously matched state of charge (SOC) corresponding to an open circuit voltage (OCV: open).

15. The method of claim 14, wherein the compensated state of charge is a state of charge in which a corresponding open circuit voltage is added to a preset specific value.

16. The method of claim 10, wherein the noise removing step includes:
comparing the internal resistance with preset values to select the open circuit using method when the internal resistance is larger than a preset threshold resistance value and the current value is 0; and
selecting the output accumulation method when the internal resistance is smaller than the preset threshold resistance value and the current value is not 0.

17. The method of claim 10, further comprising:
a battery initial state of charge estimating step of calculating a battery initial state of charge using the preset lookup table, when the current value and the voltage value are delayed by a predetermined time or more.

18. The method of claim 11, wherein the internal resistance is calculated by Equation R=±{(V−OCV)/I},
wherein I represents the current value, OCV represents the unique voltage value of the battery, ±represents a current sign, and V represents the voltage value.
